(19) United States
(12) Patent Application Publication
(10) Pub. No.: US 2015/0034159 A1
(43) Pub. Date: Feb. 5, 2015

(54) Hole-blocking TiO2/Silicon Heterojunction for Silicon Photovoltaics

(71) Applicant: THE TRUSTEES OF PRINCETON UNIVERSITY, Princeton, NJ (US)

(72) Inventors: Sushobhan Avasthi, Princeton, NJ (US); James C. Sturm, Princeton, NJ (US); William E. McClain, Princeton, NJ (US); Jeffrey Schwartz, Princeton, NJ (US)

(73) Assignee: The Trustees of Princeton University, Princeton, NJ (US)

(21) Appl. No.: 14/385,347

(22) PCT Filed: Mar. 14, 2013
(86) PCT No.: PCT/US13/31544

§ 371 Date: Sep. 15, 2014

Related U.S. Application Data
(60) Provisional application No. 61/610,891, filed on Mar. 14, 2012.

(51) Int. Cl. H01L 31/074; H01L 31/0224; H01L 31/18

(52) U.S. Cl. CPC H01L 31/074; H01L 31/18; H01L 31/022475
USPC 136/261; 438/94

(57) ABSTRACT

A hole-blocking silicon/titanium-oxide heterojunction for silicon photovoltaic devices and methods of forming are disclosed. The electronic device includes at least two electrodes having a current path between the two electrodes. The electronic device also includes a heterojunction formed of a titanium-oxide layer deposited over a Si layer and being disposed in the current path. The heterojunction is configured to function as a hole blocker. The first electrode may be electrically coupled to the Si layer and a second electrode may be electrically coupled to the titanium-oxide layer. The device may also include a PN junction disposed in the Si layer, in the current path. The device may also include an electron-blocking heterojunction on silicon in the current path.

### CROSS-REFERENCE TO PRIOR FILED APPLICATIONS

This application claims priority to earlier filed provisional applications 61/610,891 which was filed on Mar. 14, 2012, which is incorporated herein in its entirety.

### STATEMENT REGARDING FEDERALLY SPONSORED RESEARCH OR DEVELOPMENT

This invention was made with government support under Grant No. DE-EE0005315 awarded by the Department of Energy and Grant No. DMR-0819860 awarded by the National Science Foundation. The government has certain rights in the invention.

### FIELD OF INVENTION

This invention relates to the field of semiconducting devices more specifically to the formation and use of titanium-oxide heterojunctions for blocking holes in such devices.

### BACKGROUND

In electronic devices the ability to impede the flow of one type of carriers, e.g. holes, without affecting the flow of the other type of carrier, e.g. electrons, is useful. Such carrier-selective blocking layers are used in several electronic devices, such as bipolar transistors, low leakage diodes, solar cells, etc. One method of implementing a blocking layer is via a semiconducting wide-bandgap heterojunction—a junction where the second semiconductor has a bandgap wider than that of silicon. On silicon, such wide-bandgap heterojunctions are difficult to form. This disclosure generally encompasses a wide-bandgap heterojunction—between a titanium-oxide and crystalline silicon. The titanium-oxide/silicon heterojunction impedes the flow of holes without disturbing the flow of electrons. The structure is expected to be of use in, but not limited to, low-leakage diodes, low-cost high-efficient photovoltaic devices, light sensors and high-gain bipolar transistors.

### SUMMARY OF THE INVENTION

A hole-blocking silicon/titanium-oxide heterojunction for silicon photovoltaic devices and methods of forming are disclosed. The electronic device includes at least two electrodes having a current path between the two electrodes. The electronic device also includes a heterojunction formed of a titanium-oxide layer deposited over a Si layer and being disposed in the current path. The heterojunction is configured to function as a hole blocker. The first electrode may be electrically coupled to the Si layer and a second electrode may be electrically coupled to the titanium-oxide layer. The device may also include a PN junction disposed in the Si layer, in the current path.

An electron blocking layer may be electrically coupled to the silicon layer in the current path. The electron blocking layer may form a heterojunction with the Si layer. At least one electrode may be transparent or patterned. The device may be a photovoltaic device. The device may also include a passivation layer coupled between the titanium-oxide layer and the Si layer, the passivation being disposed in the current path.

A method of forming an electronic device is also disclosed. The method includes providing at least two electrodes having a current path between the two electrodes. A heterojunction is formed of a titanium-oxide layer deposited over a Si layer. The heterojunction is disposed in the current path and is configured to function as a hole blocker. The titanium-oxide layer may be formed by using titanium-alkoxide as the precursor on the Si layer. The titanium-oxide layer may be formed using a titanium (IV) tert-butoxide as a precursor.

The first electrode may be electrically coupled to the Si layer and a second electrode may be electrically coupled to the titanium-oxide layer. A PN junction may be disposed in the Si layer, in the current path. An electron blocking layer may be electrically coupled to the silicon layer in the current path. The electron blocking layer may form a heterojunction with the Si layer. At least one electrode may be transparent or patterned. The resulting device may be a photovoltaic device. A passivation layer may be coupled between the titanium-oxide layer and the Si layer, the passivation being disposed in the current path.

### BRIEF DESCRIPTION OF THE FIGURES

FIG. 1.1 is a diagram showing band-alignment of an electron-blocking layer;

FIG. 1.2 is a diagram showing band-alignment of a hole-blocking layer;

FIG. 2.1 is a schematic of a p-n homojunction photovoltaic device;

FIG. 2.2 is a band-diagram of the photovoltaic device of FIG. 2.1 under illumination and connected to external load;

FIG. 2.3 is a band-diagram of the photovoltaic device of FIG. 2.1 in dark and an external voltage;

FIG. 3.1 is a schematic of a photovoltaic device embodiment with a hole-blocking silicon/titanium-oxide heterojunction on p-doped Si;

FIG. 3.2 is a band-diagram of the photovoltaic device of FIG. 3.1 in dark and connected to an external voltage;

FIG. 4.1 is a schematic of a photovoltaic device embodiment with a hole-blocking silicon/titanium-oxide heterojunction on silicon with a p-n junction in its current path;

FIG. 4.2 is a band-diagram of the photovoltaic device of FIG. 4.1 in dark and connected to an external voltage;

FIG. 5 is a schematic of a photovoltaic device embodiment with a hole-blocking silicon/titanium-oxide heterojunction on silicon with a passivation layer between silicon and titanium-oxide layer.

FIG. 6.1 is a schematic of a photovoltaic device embodiment with a hole-blocking silicon/titanium-oxide heterojunction and an electron-blocking heterojunction on n-type silicon;

FIG. 6.2 is a band-diagram of the photovoltaic device of FIG. 6.1 in dark and connected to an external voltage;

FIG. 7.1 is a schematic of a photovoltaic device embodiment with a hole-blocking silicon/titanium-oxide heterojunction and an electron-blocking heterojunction on p-type silicon;

FIG. 7.2 is a band-diagram of the photovoltaic device of FIG. 7.1 in dark and connected to an external voltage;

FIG. 8 is a schematic of a photovoltaic device embodiment with a hole-blocking silicon/titanium-oxide heterojunction and an electron-blocking heterojunction on passivated silicon surface;

FIG. 9.1 is a schematic of an exemplar pSi/TiO₂ heterojunction photovoltaic device; and

FIG. 9.2 is a graph showing the current-voltage characteristics for the heterojunction photovoltaic device of FIG. 9.1 in dark and under AM 1.5 illumination.

### DETAILED DESCRIPTION OF THE INVENTION

Definitions

“holes” as used herein refers to the positively charged carriers in semiconducting materials.

“electrons” as used herein refers to the negatively charged carriers in semiconducting materials.

“titanium-oxide” as used herein is a material primarily comprised of one of the many known titanium oxides, such as TiO, Ti₂O₃, TiO₂, Ti₂O₅ or non-stoichiometric composition thereof (TiOₓ, where 0.1<x<3). The titanium-oxide layer may be doped or undoped.

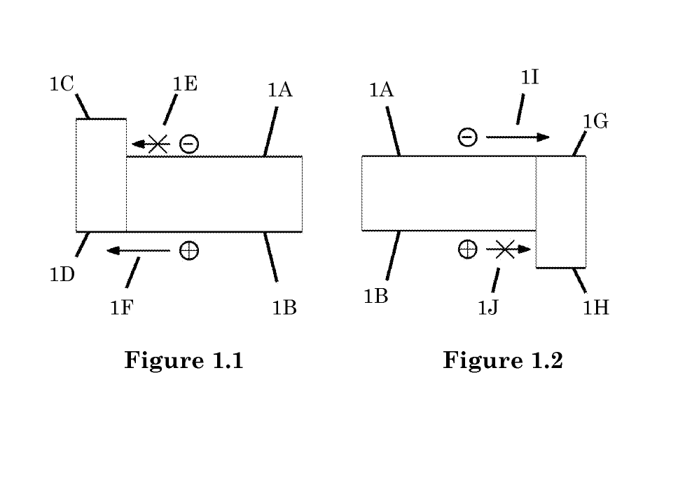

“homojunction” as used herein is a p-n junction made out of the same semiconducting material, that has been doped p-type (excess holes) and n-type (excess electrons) in different regions. See e.g., FIGS. 1.1 to 1.2.

“heterojunction” as used herein is a junction of two semiconductors where at least one of the conduction band minimum energy and/or the valence band maximum energy compared to the vacuum level energy is different in the two materials. Typically, one semiconductor has a relatively narrow bandgap and one a relatively wide bandgap compared to each other.

“valence-band edge” or equivalently the “valence band maximum energy” as used herein refers to the upper edge of the valence-band (Ev) of a semiconductor. Depending on the convention for the type of semiconductor, this may also refer to the highest occupied molecular orbital (HOMO) of the semiconductor.

“conduction-band edge” or equivalently the “conduction band minimum energy” as used herein refers to the lower edge of the conduction-band (Ec) of a semiconductor. Depending on the convention for the type of semiconductor, this may also refer to the lowest unoccupied molecular orbital (LUMO) of the semiconductor.

“carrier blocking layer” as used herein refers to either an electron blocking layer, a hole blocking layer or a layer which blocks both electrons and holes.

“electron-blocking layer” as used herein is a semiconductor that allows the unimpeded through transport of holes but prevents the through transport of electrons from silicon into the second semiconductor. In a silicon heterojunction this may be achieved by an approximate alignment of the energy of the valence-band edge (Ev) of the material with the energy of the valence-band edge (Ev) of silicon and a substantially higher energy of the conduction-band edge (Ec) of the material than the energy of the conduction-band edge (Ec) of the silicon (see e.g., FIG. 1.1).

“hole-blocking layer” as used herein is a semiconductor that allows the unimpeded through transport of electrons but prevents the through transport of holes from silicon into the second semiconductor. In a silicon heterojunction this may be achieved with an approximate alignment of the energy of the conduction-band edge (Ec) of the material with the energy of the conduction-band edge (Ec) of silicon, and a substantially lower energy of the valence-band edge (Ev) of the material than the energy of the valence-band edge of the silicon (Ev) (see e.g., FIG. 1.2).

“Surface passivation” as used herein is the removal of electrically active midgap defects on the surface of a semiconductor, usually by a chemical treatment, annealing step, or deposition of a passivation layer.

“Low-temperatures” as used herein are temperatures below or about 200° C.

Traditionally, the flow of holes and electrons in electronic devices, such as bipolar transistors, diodes and solar cells is manipulated using doped p-n homojunctions. In some cases it is beneficial to use wide-bandgap heterojunctions to augment, or replace, the traditional p-n junction [H. Kroemer, Surface Science, 1983, 132, pp 543]. Disclosed herein is a wide-bandgap heterojunction between crystalline silicon and titanium-oxide that overcomes these issues.

One advantage of wide-bandgap heterojunctions is that they can be engineered to selectively block only one of carriers—either electron of holes. In this disclosure, the heterojunctions that only block electrons are referred to as “electron-blocking heterojunctions”, while those that block only holes are referred to as “hole-blocking heterojunctions”.

Electrons may be blocked by engineering the second semiconductor such that the energy of the “highest occupied molecular orbital” (HOMO) or valence-band edge (Ev) of the second material is almost aligned with the energy of the valence-band edge (Ev) of silicon, while the energy of the “lowest unoccupied molecular orbital” (LUMO)/conduction-band edge (Ec) of the second material is much higher than the energy of the conduction band edge (Ec) of the silicon. Due to the difference in the Ec of the two materials, the electrons in silicon trying to flow in to the second material experience a large potential energy barrier. This barrier reduces the electron current (see e.g., FIG. 1.1).

Holes may be blocked by engineering the second semiconductor such that the energy of the LUMO/Ec of the second material aligns with the energy of the Ec of silicon, while the energy of the HOMO/Ev of the second material is much lower than the energy of the Ev of silicon. Due to the difference in the Ev of the two materials, the holes in silicon trying to flow in to the second material experience a large potential energy barrier. This barrier reduces the holes current (see e.g., FIG. 1.2).

These design rules for the band-alignment of an electron and hole-blocking heterojunctions are highlighted in FIGS. 1.1 and 1.2. FIG. 1.1 shows that band-alignment at the interface of an electron-blocking heterojunction in silicon. In FIG. 1.1, the following reference numbers apply:

1A: Conduction-band edge of silicon (Ec);

1B: Valence-band edge of silicon (Ev);

1C: LUMO or conduction-band edge of the electron-blocking layer;

1D: HOMO or valence-band edge of the electron-blocking layer;

1E: Electron transport is impeded; and

1F: Holes transport is not impeded;

FIG. 1.2 shows the band-alignment at the interface of a hole-blocking heterojunction in silicon. The following reference numbers apply:

1A: Conduction-band edge of silicon (Ec);

1B: Valence-band edge of silicon (Ev);

1G: LUMO or conduction-band edge of the hole blocking layer;

1H: HOMO or valence-band edge of the hole blocking layer;

1I: Electron transport is unimpeded; and

1J: Hole-transport is impeded.

Thin layers of titanium-oxide were found to be semiconducting. Band-alignment at the silicon/titanium-oxide was such that the difference in Ev was 3.4 eV, while the difference in Ec was only a few tenths of an eV. The silicon/titanium-oxide interface is expected to block holes in silicon attempting to flow into the titanium-oxide, while allowing electrons to flow through unimpeded. The fact that the silicon/titanium-oxide heterojunction blocks holes was also corroborated by the current-voltage characteristics of silicon/titanium-oxide diodes described in U.S. provisional application No. 61/610,891.

Titanium-oxide can naturally occur is several forms, e.g. TiO, Ti₂O₃, TiO₂, Ti₂O₅, etc. and other non-stoichiometric compositions. Any of these forms may be used for purposes of making the heterojunction. Titanium-oxide as defined in this disclosure refers to any layer that primarily comprises of a mix of any of the forms of titanium-oxide. Other elements may also be added such as nitrogen, but the layer should predominantly contain titanium and oxygen.

There are several applications for a hole-blocking heterojunction on silicon, e.g. in high-gain heterojunction transistors, low-leakage diodes, and solar cells. To illustrate the principles, here we discuss some embodiments of solar cells made using the silicon/titanium-oxide heterojunction.

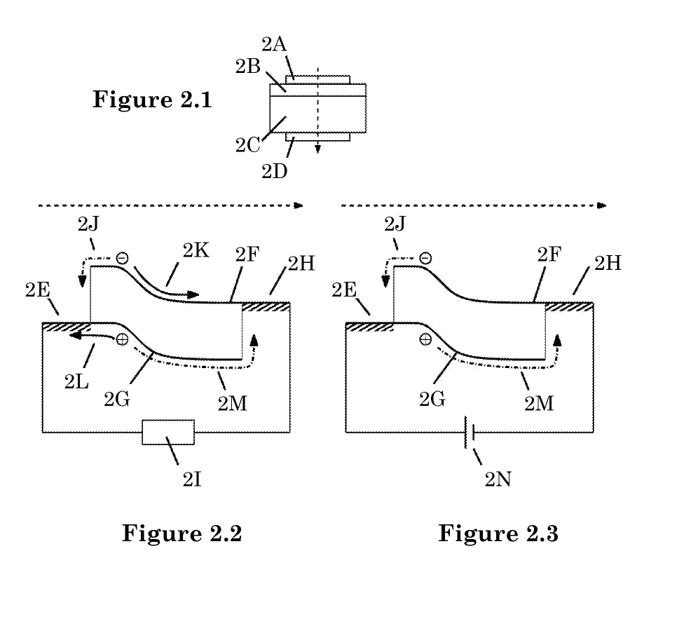

Consider a simple p-n homojunction solar cell. FIG. 2.1 shows the structure the p-n homojunction device. It consists of an electrode 2A, a p-type silicon layer 2B, an n-type silicon layer 2C and a second electrode 2D. Either of 2A or 2D may be transparent or patterned to allow transmission of light. Due to the difference in doping, there exists a “built-in” electric field at the interface of p and n-doped regions in silicon.

Under illumination, light is absorbed in silicon, generating electron and holes in silicon. The built-in field causes the photogenerated electrons and holes to separate and flow towards opposite electrodes, electrode 2 and electrode 1, respectively, yielding a photocurrent.

However the carrier separation is not perfect. Some carriers flow in the “wrong” direction due to the relatively positive voltage on the p-type side vs. the n-type side in photovoltaic operation and are lost to recombination at the electrodes. For improving device performance, it is desirable to reduce these losses. FIG. 2.2 is a band-diagram of FIG. 2.1 under illumination and connected to external load 2I. It shows the flow direction of the photocurrent and the current due to the loss pathways. In FIGS. 2.2 and 2.3 the following reference numbers apply:

2E: Electrode 1 Fermi-level;

2F: Conduction-band edge of silicon;

2G: Valence-band edge of silicon;

2H: Electrode 2 Fermi-level;

2I: External Load;

2J: Electron recombination current (loss pathway);

2K: Light-induced electron photocurrent;

2L: Light-induced hole photocurrent; and

2M: Hole recombination current (loss pathway).

In the dark, there is no photocurrent, but the “loss” pathways (2J and 2M) are still active. Hence, measuring this “dark-current” is a direct measure of the loss pathways in a solar cell—higher the dark-current, higher the losses. FIG. 2.3 is a band-diagram of FIG. 2.1 under dark and connected to an external voltage 2N, showing the components of the dark-current.

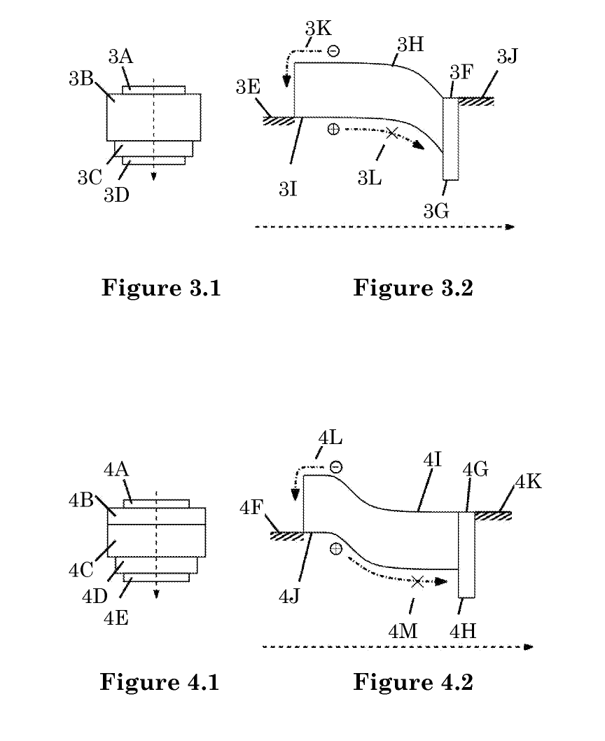

FIG. 3.1 is a schematic of a photovoltaic device embodiment that replaces the p-n junction with a hole-blocking silicon/titanium-oxide heterojunction. The photovoltaic device has a first electrode 3A, p-type silicon layer 3B, titanium-oxide layer 3C and second electrode 3D. Either one of the electrodes 3A or 3D may be transparent or patterned to allow transmission of light. Like the p-n homojunction device (FIG. 2.1-2.3), the heterojunction solar cell also has a built-in field in silicon to separate the photogenerated carriers. This built-in field exists either due to the work-function difference between the silicon and titanium-oxide or due to work-function difference between the silicon and electrode 3D.

Due to the large difference in the Ev of the titanium-oxide and silicon, the holes experience a barrier that is larger than what they experience in p-n homojunction. This may lead to much lower hole recombination currents in heterojunction devices. FIG. 3.2 is a band-diagram of the heterojunction photovoltaic device of FIG. 3.1 in dark under and connected to an external voltage. The following reference numbers apply:

3E: Electrode 1 Fermi-level;

3F: Conduction-band edge of titanium-oxide;

3G: Valence-band edge of titanium-oxide;

3H: Conduction-band edge of silicon;

3I: Valence-band edge of silicon;

3J: Electrode 2 Fermi-level;

3K: Electron recombination current (loss mechanism); and

3L: Hole recombination current (loss mechanism) is reduced due to valence band barrier.

Another embodiment of the heterojunction solar cell may be a structure in which silicon already has a p-n homojunction. The role of hole-blocking heterojunction in such a cell would be to improve the performance of a p-n junction solar cell by further reducing the losses due to hole recombination. FIG. 4.1 is a schematic of such a photovoltaic device. The photovoltaic device includes a first electrode 4A, a p-type silicon layer 4B, an n-type silicon layer 4C, titanium-oxide layer 4D and a second electrode 4E. Either electrodes 4A or 4E may be transparent or patterned.

As before, due to the large difference in the Ev of the titanium-oxide and silicon, the hole recombination currents in heterojunction devices are lower. FIG. 4.2 is a band-diagram of the FIG. 4.1 under dark and connected to an external voltage. The following reference number apply:

4F: Electrode 1 Fermi-level;

4G: Conduction-band edge of titanium-oxide;

4H: Valence-band edge of titanium-oxide;

4I: Conduction-band edge of silicon;

4J: Valence-band edge of silicon;

4K: Electrode 2 Fermi-level;

4L: Electron recombination current (loss mechanism); and

4M: Hole recombination current (loss mechanism) is reduced due to barrier.

The embodiments of solar cells described above, only reduce hole-recombination current, but leave the electron recombination current unchanged. One way to reduce the electron recombination is to engineer the silicon substrate. Use of better quality silicon substrates with higher recombination lifetimes, such as Float-zone silicon, and/or increase the silicon doping level will reduce electrons recombination losses. Another way to reduce losses in these solar cells is by adding an electron-blocking heterojunction to the device stack.

Electron-blocking heterojunction on silicon, using organic semiconductors has been previously disclosed in S. Avasthi et al. [doi: 10.1063/1.3429585]. Similar heterojunction may be used as devices to block electrons.

Double-sided heterojunction have been previously demonstrated using amorphous silicon (and amorphous silicon alloys) to make silicon photovoltaic devices. Typically, the crystalline silicon substrate is n-type, onto which a thin layer of p-doped amorphous silicon is grown. This junction is referred to as a Heterojunction with an Intrinsic Thin layer or a “HIT” junction (see Tanaka M. et al., 2003, Proceedings of the 3rd World Conference on Photovoltaic Energy Conversion, Vol. 1, pp 955-958 doi: 10.1109/WCPC.2003.1305441; and, Tanaka M. et al. 1993, Jpn. J. Appl. Phys. Vol. 31, pp. 3518-3522, both of which are hereby incorporated by reference in their entirety). On the other side of the crystalline silicon, an n⁺-doped amorphous silicon layer is grown. This creates a p-n-n⁺ junction—the frontside p-n junction for blocking electrons and the backside n-n⁺ junction for blocking holes. While the HIT junction is effective, the fabrication is done in a plasma-enhanced chemical vapor deposition system at 300-400° C. using dangerous gases. This adds a degree of complexity and cost to the fabrication of the HIT junction. Furthermore, the HIT device uses the same material, amorphous silicon, on both sides of the device. This does not allow the independent tuning of abrupt conduction and valence band offsets at the interface with the silicon substrate on the two sides.

FIG. 6.1 is a schematic of a photovoltaic device embodiment with both, an electron-blocking layer and a hole-blocking titanium-oxide layer on n-type silicon. The photovoltaic device has a first electrode 6A, an electron-blocking layer 6B, an n-type silicon layer 6C, titanium-oxide layer 6D and a second electrode 6E. Either of the electrodes 6A or 6E may be transparent or patterned.

FIG. 6.2 is a band-diagram of the photovoltaic device of FIG. 6.1 under dark and connected to an external voltage. The following reference numbers apply:

6F: Electrode 1 Fermi-level;

6G: LUMO or conduction-band edge of the electron-blocking layer;

6H: HOMO or valence-band edge of the electron-blocking layer;

6I: Conduction-band edge of silicon;

6J: Valence-band edge of silicon;

6K: Conduction-band edge of titanium-oxide;

6L: Valence-band edge of titanium-oxide;

6M: Electrode 2 Fermi-level;

6N: Electron recombination current (loss mechanism) is reduced due to Ec barrier; and

6O: Hole recombination current (loss mechanism) is reduced due to Ev barrier.

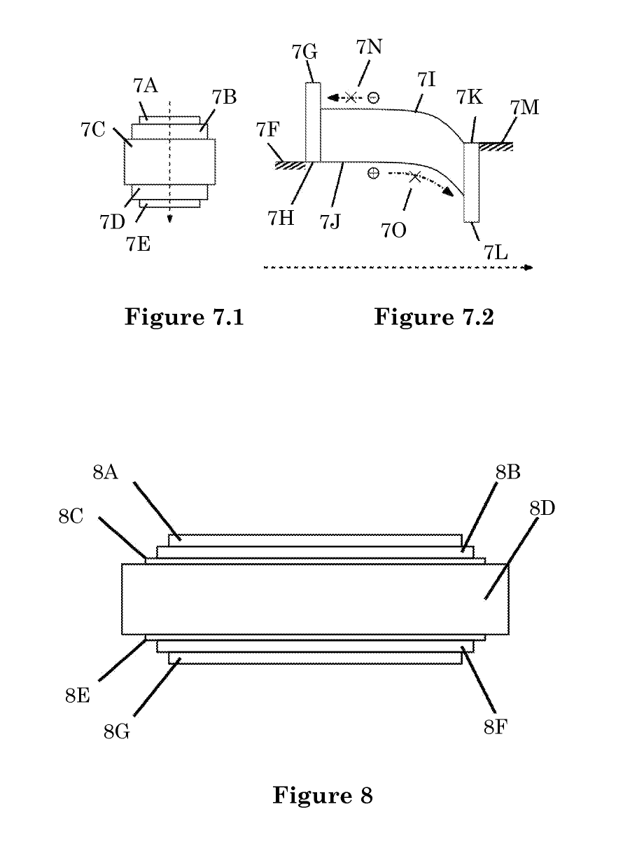

A closely related but different embodiment of a double sided heterojunction may use p-doped silicon instead of n-doped silicon. FIG. 7.1 is a schematic of the embodiment of the photovoltaic device with an electron-blocking layer and a hole-blocking titanium-oxide layer on p-type silicon. The photovoltaic device has a first electrode 7A, an electron-blocking layer 7B, a p-type silicon layer 7C, titanium-oxide layer 7D and a second electrode 7E. Either of the electrodes 7A or 7E may be transparent or patterned.

FIG. 7.2 is a band-diagram of the photovoltaic device of FIG. 7.1 under dark and connected to an external voltage. The following reference numbers apply:

7F: Electrode 1 Fermi-level;

7G: LUMO or conduction-band edge of the electron-blocking layer;

7H: HOMO or valence-band edge of the electron-blocking layer;

7I: Conduction-band edge of silicon;

7J: Valence-band edge of silicon;

7K: Conduction-band edge of titanium-oxide;

7L: Valence-band edge of titanium-oxide;

7M: Electrode 2 Fermi-level;

7N: Electron recombination current (loss mechanism) is reduced due to Ec barrier; and

7O: Hole recombination current (loss mechanism) is reduced due to Ev barrier.

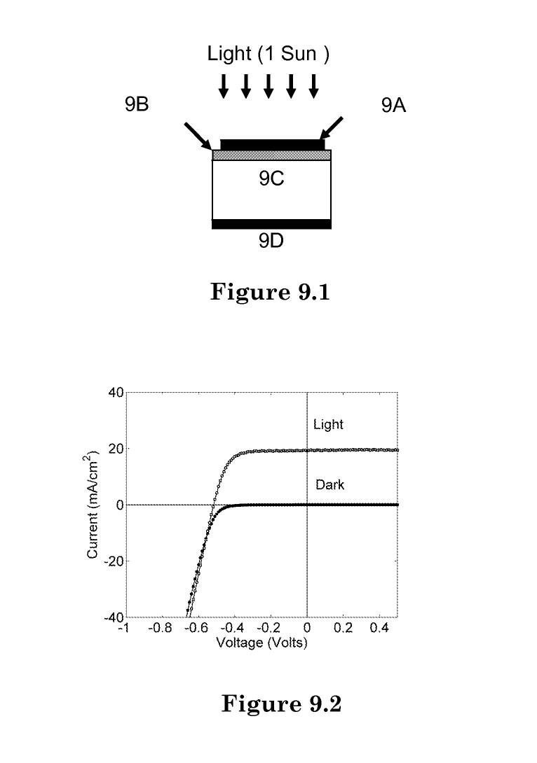

An example silicon/titanium-oxide photovoltaic device is shown in FIG. 9.1. The solar cell comprises of a 15 nm thick semi-transparent aluminum layer, serving as the first electrode (9A). A p-doped silicon wafer (9B). A 3 nm thick titanium-oxide layer (9C). Finally a 200 nm silver layer, serving as the second electrode (9D). The light is absorbed in silicon. The photogenerated carriers are separated by the TiO₂/p-Si heterojunction. The current-voltage characteristics in dark and under AM 1.5 conditions (FIG. 9.2) clearly show characteristic solar cell response, with an open-circuit voltage of 0.52 V and a short-circuit current of 19.3 mA/cm².

Traditionally, fabricating wide-bandgap heterojunctions on crystalline silicon (bandgap Eg=1.12 eV) had proved to be challenging, primary due to the lattice mismatch between silicon and the other semiconductor [H. Kroemer, Surface Science, 1983, 132, pp 543]. The mismatch is small for the narrow bandgap Si₁₋ₓGeₓ alloys (Eg=0.8-1.1 eV), only ˜1% for x=0.25, and narrow bandgap heterojunctions can be fabricated on silicon by compressively straining thin SiGe layers to match the silicon lattice [J. C. Bean, et al., J. Vac. Sci. Technol. A, 1984, 2, 436]. However, this pseudomorphic lattice matching is not feasible for making wide bandgap heterojunction on silicon using wideband gap column IV semiconductors, e.g. 3C—SiC (Eg=2.4 eV) and diamond (Eg=5.4 eV) [J. Pelletier, et al., J. Appl. Phys., 1984, 55, 994]. Though both 3C—SiC and diamond have the same lattice structure as silicon, their lattice constants are 20% and 35% smaller than that of silicon, making the mismatch too large to be compensated by straining thin layers [C. Long, et al, J. Appl. Phys., 1999, 86, 2509].

Silicon/titanium-oxide heterojunctions avoid the issue of lattice mismatch by using amorphous or poly-crystalline titanium-oxide layers. However the silicon may still be crystalline and unsatisfied valencies of the silicon atoms at the crystalline silicon surface may cause electrically active midgap defect states. These “surface-states” on the silicon surface also lead to recombination losses. Therefore, it was determined the surface-states should be removed, e.g. by passivating the silicon surface.

One way to passivate silicon is to satisfy the unsatisfied valencies on the silicon surface by introducing an intermediate layer between silicon and titanium-oxide layer. Since such a layer is positioned between the silicon surface and the titanium-oxide layer, within the path of the current flow, it is critical that it not impede the transport of holes through it. This may be achieved by making the intermediate layers so thin so that holes can tunnel though any potential barrier. This may also be achieved by having the Ev/HOMO arranged so as to not block holes.

Another way to passivate silicon is to treat the structure under suitable temperature and ambient conditions such that titanium-oxide itself reacts with silicon. In this case the unsatisfied bonds on silicon will be satisfied by the titanium-oxide itself.

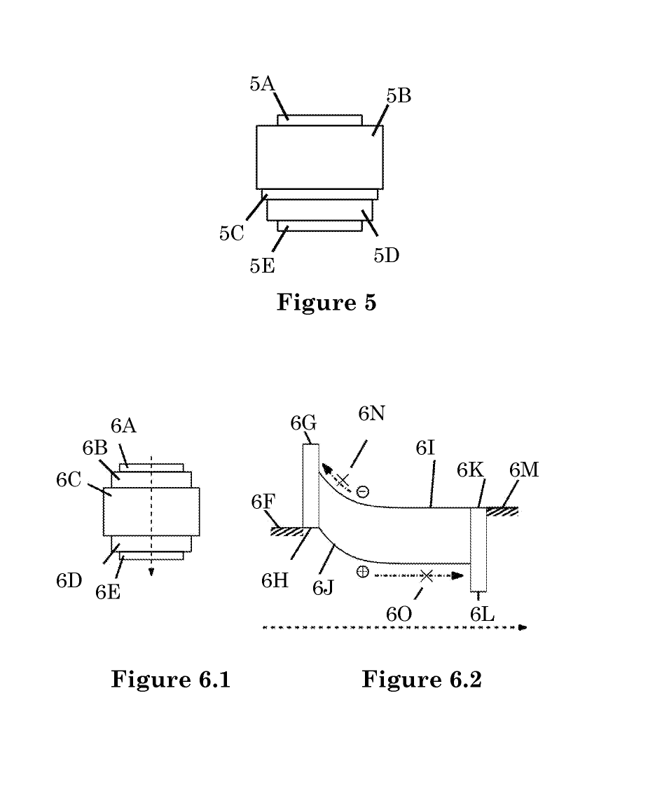

A suitable passivation scheme may be incorporated in any device using silicon-titanium-oxide heterojunction, including the device embodiments described above. For example, FIG. 5 is a schematic of a photovoltaic device embodiment comprising of a single-sided silicon/titanium-oxide solar cell with passivation. The silicon layer in the device may or may not have p-n junction in its current path. The photovoltaic device has a first electrode 5A, a silicon layer 5B, a passivation layer 5C, titanium-oxide layer 5D and a second electrode 5E. Either of the electrodes 5A or 5E may be transparent or patterned. Also, FIG. 8 is a schematic of double-sided heterojunction solar cell (with both electrons and hole-blocking layers) with passivation. The device has a first electrode 8A, an electron-blocking layer 8B, an optional passivation layer 8C that allows conduction of holes, a silicon layer 8D, an optional passivation layer 8E that allows conduction of electrons, a hole-blocking titanium-oxide layer 8F, and a second electrode 8G. Either of the electrodes 8A or 8G may be transparent or patterned.

The titanium dioxide is deposited on silicon by a chemical vapor deposition process that uses titanium (IV) tetra-(tert-butoxide) as the precursor. Prior to deposition, the silicon surface us cleaned using solvents (like acetone, alcohols, etc), bases (such as ammonium hydroxide) and acids (hydrochloric acid, sulfuric acid, hydrofluoric acid, etc). Typical deposition cycle consists of two steps. First, the silicon wafer is cooled (0 to −10° C.) and vapors of the Ti-alkoxide are introduced into the chamber. This step forms a thin layer of the Ti-alkoxide on the silicon surface. Second, the silicon wafer is heated (80 to 100° C.) to thermolyze the Ti-alkoxide into titanium dioxide. Depending on the temperature and length of the cooling cycle, one complete cycle results in the deposition of 1-4 nm of titanium dioxide. Thicker films may be deposited by repeating the deposition cycle multiple times.

In general, any titanium metal-organic precursor can be used to deposit titanium-oxide onto silicon. An incomplete list of examples includes titanium-tetrachloride, titanium tetrabromide, and titanium-isopropoxide.

All the device embodiments described here have relied on mono-crystalline silicon. However, heterojunctions may be produced by these methods using other types of silicon. For instance, it is envisioned the construction of heterojunctions photovoltaic devices using various silicon alloys (SiGe, SiC, SiGeC, etc), multicrystalline silicon, microcrystalline silicon, upgraded metallurgical-grade silicon, ribbon silicon, thin-film silicon, and combinations thereof. It is also envisioned that such heterojunctions of these types of silicon may be used in photovoltaic devices, including solar cells, diodes, and transistors.

The low-temperature of fabrication of silicon/titanium-oxide heterojunction adds another dimension to its usefulness. Unlike the p-n junctions that it replaces, which are fabricated at temperatures in excess of 800 C, the silicon/titanium-oxide heterojunction is fabricated at temperature of only 100° C. by a simplified vapor deposition process. This reduces both the complexity of the fabrication process and cost. Even when compared to the competing HIT structure, which is fabricated at ˜300 C, the silicon/titanium-oxide structure may have a potential cost advantage.

In conclusion, the disclosed devices demonstrate a novel low-temperature processed TiO₂/Si heterojunction that selectively blocks in silicon. Although features and elements are described above in particular combinations, each feature or element may be used alone without the other features and elements or in various combinations with or without other features and elements.

What is claimed is:

1. A electronic device comprising:
at least two electrodes having a current path between the two electrodes; and
a heterojunction formed of a titanium-oxide layer deposited over a Si layer and being disposed in the current path, the heterojunction being configured to function as a hole blocker.

2. The device of claim 1, wherein a first electrode is electrically coupled to the Si layer and a second electrode is electrically coupled to the titanium-oxide layer.

3. The device of claim 1, further comprising a PN junction disposed in the Si layer, in the current path.

4. The device of claim 3, further comprising an electron blocking layer electrically coupled to the silicon layer in the current path.

5. The device of claim 4, wherein the electron blocking layer forms a heterojunction with the Si layer.

6. The device of claim 2, further comprising an electron blocking layer electrically coupled to the silicon layer in the current path.

7. The device of claim 6, wherein the electron blocking layer forms a heterojunction with the Si layer.

8. The device of claim 1, wherein at least one of the electrodes is transparent or patterned.

9. The device of claim 1, wherein the device is configured as a photovoltaic device.

10. The device as in any one of the preceding claims, further comprising a passivation layer coupled between the titanium-oxide layer and the Si layer and being disposed in the current path.

11. A method of forming an electronic device, the method comprising:
providing at least two electrodes having a current path between the two electrodes; and
forming a heterojunction of a titanium-oxide layer deposited over a Si layer and being disposed in the current path, the heterojunction being configured to function as a hole blocker.

12. The method of claim 11, wherein the titanium-oxide layer is formed by using titanium-alkoxide as the precursor on the Si layer.

13. The method of claim 11, wherein the titanium-oxide is formed using a titanium (IV) tert-butoxide as a precursor.

14. The method of claim 11, further comprising electrically coupling a first electrode to the Si layer and electrically coupling a second electrode to the titanium-oxide layer.

15. The method of claim 11, further comprising forming a PN junction disposed in the Si layer, in the current path.

16. The method of claim 15, further, further comprising forming an electron blocking layer electrically coupled to the silicon layer in the current path.

17. The method of claim 16, wherein the electron blocking layer forms a heterojunction with the Si layer.

18. The method of claim 11, further, further comprising forming an electron blocking layer electrically coupled to the silicon layer in the current path.

19. The method of claim 18, wherein the electron blocking layer forms a heterojunction with the Si layer.

20. The method of claim 11, wherein at least one of the electrodes is transparent or patterned.

21. The method of claim 11, wherein the device is configured as a photovoltaic device.

22. The method as in any one of the preceding claims, further comprising forming a passivation layer coupled between the titanium-oxide layer and the Si layer and being disposed in the current path.
